(19) United States
(12) Patent Application Publication
(10) Pub. No.: US 2026/0003297 A1
(43) Pub. Date: Jan. 1, 2026

(54) CONVEYANCE APPARATUS, LITHOGRAPHY APPARATUS, AND ARTICLE MANUFACTURING METHOD

(71) Applicant: CANON KABUSHIKI KAISHA, Tokyo (JP)

(72) Inventor: KIMIO TAKEYA, Tochigi (JP)

(21) Appl. No.: 19/249,592

(22) Filed: Jun. 25, 2025

(30) Foreign Application Priority Data
Jul. 1, 2024 (JP) 2024-106281

(51) Int. Cl. G03F 7/00

(52) U.S. Cl. CPC G03F 7/70725; G03F 7/7085; G03F 7/70991

(57) ABSTRACT

The aspect of the embodiments, provides an apparatus comprising: a measurement device configured to measure foreign particles on a surface of an object; a conveyer including a holder configured to hold the object while contacting a part of the surface of the object, and configured to convey the object for which the foreign particles have been measured, while holding the object by the holder; and a controller configured to control conveying the object by the conveyer, in accordance with specific foreign particles in a contact region to which the holder contacts among the surface of the object, wherein the specific foreign particles are obtained from a measurement result of the measurement device.

### BACKGROUND

### Field of the Technology

The disclosure relates to a conveyance apparatus, a lithography apparatus, and an article manufacturing method.

### Description of the Related Art

A lithography apparatus that forms a pattern on a substrate is provided with a conveyance apparatus that conveys an object such as an original or a substrate while holding the object by vacuum suction or the like. The lithography apparatus is required to improve productivity (throughput), and the conveyance apparatus can also be required to shorten the time taken to convey the object. Japanese Patent Laid-Open No. 2006-41386 describes that the strength of a suction force when an object is sucked and held by a suction holding means is detected and the moving speed of the suction holding means is controlled based on the detected strength of the suction force.

In a case where an object is conveyed at a high speed in accordance with a suction force, as described in Japanese Patent Laid-Open No. 2006-41386, even if the suction force is sufficient, it may be impossible to accurately convey the object. If, for example, many foreign particles adhere to a suction holding region of the front surface of the object as a conveyance target, even if the suction force is sufficient, a frictional force between the suction holding means and the object may be reduced. If the object is conveyed at a high speed in this state, the object slips off the suction holding means, and the relative position between the suction holding means and the object deviates. As a result, it is impossible to accurately convey the object onto a stage as the conveyance destination of the object, and it may take extra time to position the object. In addition, when foreign particles are sandwiched between the suction holding means and the object, the object may be distorted.

### SUMMARY

According to one aspect of the embodiments, there is provided an apparatus comprising: a measurement device configured to measure foreign particles on a surface of an object; a conveyer including a holder configured to hold the object while contacting a part of the surface of the object, and configured to convey the object for which the foreign particles have been measured, while holding the object by the holder; and a controller configured to control conveying the object by the conveyer, in accordance with specific foreign particles in a contact region to which the holder contacts among the surface of the object, wherein the specific foreign particles are obtained from a measurement result of the measurement device.

Features of the disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the disclosure, and together with the description, serve to explain the principles of the embodiments.

FIG. 1 is a schematic view showing an example of the configuration of an exposure apparatus according to the first embodiment;

FIG. 2 is a schematic view showing an example of the structure of the front surface of an original;

FIGS. 3A and 3B are schematic views showing an example of the configuration of a hand of a second conveyance mechanism;

FIG. 4 is a schematic view showing an example of the configuration of a foreign particle inspection device;

FIG. 5A is a view showing an example of a foreign particle adhesion distribution acquired by the foreign particle inspection device;

FIG. 5B is a view showing an example of the foreign particle adhesion distribution acquired by the foreign particle inspection device;

FIG. 6 is a flowchart illustrating a method of conveying the original according to the first embodiment;

FIG. 7 is a flowchart illustrating foreign particle inspection according to the second embodiment;

FIG. 8 is a flowchart illustrating a method of predicting a time when a foreign particle adhesion status in a contact region does not satisfy a predetermined condition and performing notification according to the third embodiment;

FIG. 9 is a graph showing an example of the relationship between the number of times of conveyance and the foreign particle adhesion status; and

FIG. 10 is a flowchart illustrating a method of changing a predetermined condition in accordance with the conveyance position deviation of an original according to the fourth embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

In the specification and the accompanying drawings, directions will typically be indicated on an XYZ coordinate system in which directions parallel to the horizontal plane are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively.

In the following embodiments, as a lithography apparatus that forms a pattern on a substrate, an exposure apparatus that transfers a pattern of an original such as a reticle or a mask onto a substrate by exposing the substrate will be exemplified, but the disclosure is not limited to this. For example, the disclosure can be applied to another lithography apparatus such as a shaping apparatus (imprint apparatus or planarization apparatus) that shapes a composition on a substrate using an original such as a mold. In addition, in the following embodiments, an original will be exemplified as a conveyance target object (object) conveyed by a conveyance apparatus, but the conveyance target object may be a substrate.

### First Embodiment

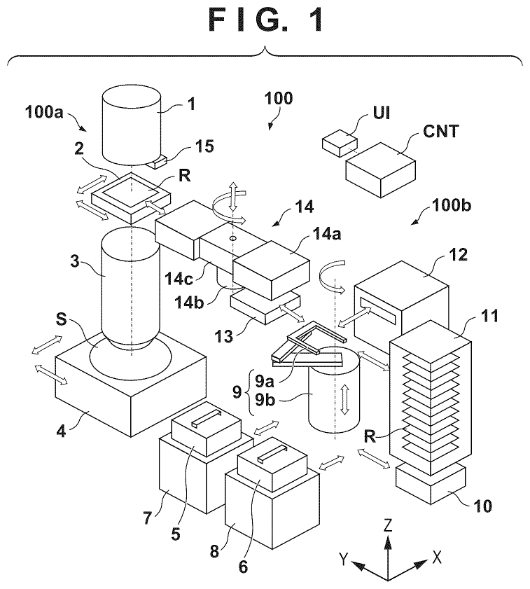

An exposure apparatus 100 according to the first embodiment of the disclosure will be described. FIG. 1 is a schematic view showing an example of the configuration of the exposure apparatus 100 according to this embodiment, and shows the inside of a chamber that covers the whole exposure apparatus 100. The exposure apparatus 100 is a step-and-scan type exposure apparatus (so-called scanner) that transfers a pattern of an original R (reticle or mask) onto a substrate S (wafer) by performing an exposure process of exposing the substrate S while relatively scanning the original R and the substrate S. The exposure process is performed for each of a plurality of shot regions on the substrate S. Note that this embodiment will exemplify the step-and-scan type exposure apparatus, but the disclosure can also be applied to a step-and-repeat type exposure apparatus (so-called stepper).

As shown in FIG. 1, the exposure apparatus 100 can include a forming apparatus 100a, an original conveyance apparatus 100b, a controller CNT, and a user interface UI. The controller CNT is formed by a computer (information processing apparatus) including a processor such as a central processing unit (CPU) and a storage unit such as a memory, and comprehensively controls the operation of the exposure apparatus 100. The controller CNT can control an exposure process performed by the forming apparatus 100a, and an original conveyance process performed by the original conveyance apparatus 100b. The user interface UI can include an input unit that accepts an input from a user (operator), and a notifier that notifies the user (operator) of information. The notifier can include, for example, a display for displaying information. Note that FIG. 1 does not illustrate the chamber that covers the whole exposure apparatus 100 and a substrate conveyance apparatus that conveys the substrate S.

The forming apparatus 100a forms a pattern on the substrate S by performing an exposure process. The forming apparatus 100a according to this embodiment can include, for example, an illumination optical system 1 that illuminates the original R, an original stage 2 that can move while holding the original R, a projection optical system 3 that projects an image of the pattern of the original R on the substrate S, and a substrate stage 4 that can move while holding the substrate S. The original R includes the pattern (for example, a circuit pattern) to be transferred onto the substrate S, and is illuminated, via the illumination optical system 1, with light generated from a light source (not shown), such as an excimer laser. The light that has passed through the original R is projected as an image of the pattern of the original R on the substrate S at a predetermined magnification by the projection optical system 3. The forming apparatus 100a according to this embodiment relatively scans the original R and the substrate S in synchronism with each other by the original stage 2 and the substrate stage 4 in a predetermined scanning direction (for example, the Y direction) at a speed ratio corresponding to the projection magnification of the projection optical system 3. This can transfer the pattern of the original R onto the substrate S.

The original conveyance apparatus 100b conveys the original R so as to load the original R to the forming apparatus 100a and unload the original R from the forming apparatus 100a. The original conveyance apparatus 100b according to this embodiment can include, for example, a first conveyance mechanism 9, a second conveyance mechanism 14, and a foreign particle inspection device 12.

The first conveyance mechanism 9 is a mechanism that conveys the original R among pod openers 7 and 8, a reticle stocker 11, the foreign particle inspection device 12, and an alignment stage 13 while holding a part of the back surface (for example, the lower surface) of the original R. The second conveyance mechanism 14 is a mechanism (conveyer) that conveys the original R between the alignment stage 13 and the original stage 2 of the forming apparatus 100a while holding a part of the front surface (for example, the upper surface) of the original R. The foreign particle inspection device 12 is a device that inspects foreign particles adhering to the front surface of the original R.

Original storage containers 5 and 6 are closed containers each of which stores one or a plurality of originals R and can open and close, and are placed on the pod openers 7 and 8, respectively. The original storage containers 5 and 6 will sometimes be referred to as SMIF pods hereinafter. The pod openers 7 and 8 are devices for opening/closing the original storage containers 5 and 6, respectively, and each include an elevating mechanism (not shown) for opening the original storage container 5 or 6 and extracting the original R from the original storage container 5 or 6. The original R extracted from the original storage container 5 or 6 by the pod opener 7 or 8 is conveyed by the first conveyance mechanism 9.

The first conveyance mechanism 9 can be formed as, for example, a conveyance robot including a hand 9a that holds a part of the back surface of the original R and a driving mechanism 9b that drives the hand 9a with respect to a plurality of axes (for example, six axes including the X-axis, Y-axis, Z-axis, θX-axis, θY-axis, and θZ-axis). The original R is unloaded from the pod opener 7 or 8 while being held by the hand 9a of the first conveyance mechanism 9, and is conveyed to the reticle stocker 11 after a code reader 10 reads the identification code of the original R. The reticle stocker 11 is a storage (stocker) that stores the plurality of originals R, and has, for example, a shelf-like structure. The plurality of originals R stored in the reticle stocker 11 can be managed by the controller CNT based on identification codes read by the code reader 10. Among the plurality of originals R stored in the reticle stocker 11, the original R to be used for the next exposure process is unloaded from the reticle stocker 11 by the first conveyance mechanism 9, and conveyed to the foreign particle inspection device 12.

The foreign particle inspection device 12 is a device that inspects the sizes, positions, and amount of foreign particles adhering to the front surface of the original R, and functions as a measurement device that measures the foreign particles on the front surface of the original R. That is, the foreign particle inspection device 12 measures the foreign particle adhesion distribution on the front surface of the original R. In a case where a pellicle is formed on the front surface of the original R, the foreign particle inspection device 12 inspects the sizes, positions, and amount of foreign particles adhering to the surface of the pellicle. The surface of the pellicle may be understood as a part of the front surface of the original R.

The original R having undergone foreign particle inspection (foreign particle measurement) by the foreign particle inspection device 12 is conveyed to the alignment stage 13 by the first conveyance mechanism 9. The alignment stage 13 aligns the original R with respect to, for example, the X direction, the Y direction, and the OZ direction so that the deviation amount of the position and posture of the original R with respect to an alignment reference falls within a predetermined range. Note that the alignment reference may be understood as a reference value (target value) concerning the position and posture of the original R.

The original R aligned by the alignment stage 13 is conveyed onto the original stage 2 of the forming apparatus 100a by the second conveyance mechanism 14. The second conveyance mechanism 14 includes a hand 14a that holds the original R while contacting a part of the front surface of the original R, and a driving mechanism 14b that drives the hand 14a. In the second conveyance mechanism 14 according to this embodiment, the hand 14a is provided in each of the two end portions of a beam-shaped support member 14c, and the driving mechanism 14b drives the hand 14a by driving the support member 14c to rotate in the OZ direction or to move up/down in the Z direction. Thus, the second conveyance mechanism 14 can hold the original R on the alignment stage 13 by the hand 14a, and convey the original R to the original stage 2 by driving the support member 14c to rotate in the OZ direction by the driving mechanism 14b.

Upon completion of the exposure process in the forming apparatus 100a, the second conveyance mechanism 14 holds the original R on the original stage 2 by the hand 14a, and conveys the original R onto the alignment stage 13 by driving the support member 14c to rotate in the OZ direction by the driving mechanism 14b. The original R on the alignment stage 13 is conveyed to the reticle stocker 11 by the first conveyance mechanism 9, and is temporarily stored. In a case where it is not scheduled to use the original R again for the exposure process, the original R is conveyed to the pod opener 7 or 8 by the first conveyance mechanism 9, and is finally stored in the original storage container 5 or 6.

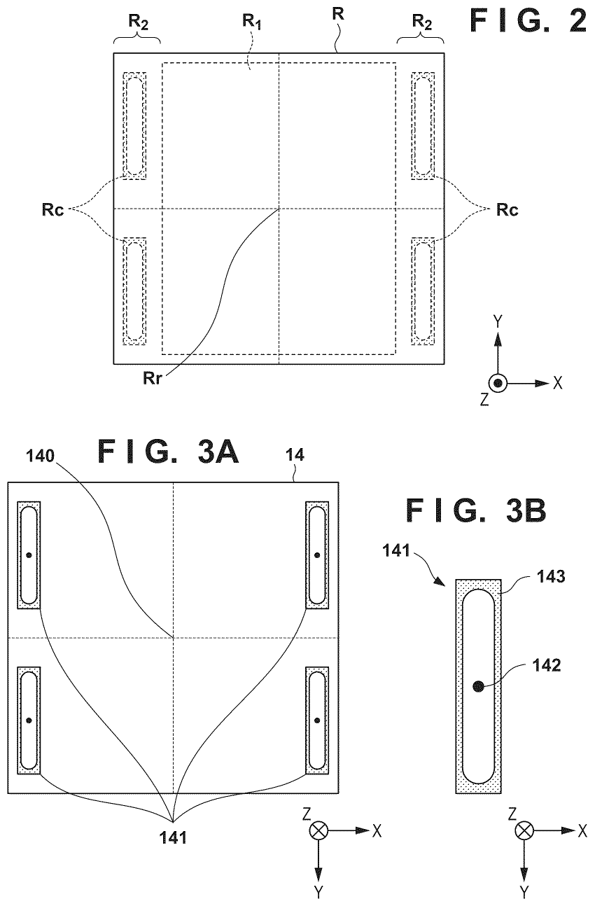

FIG. 2 is a schematic view showing an example of the structure of the front surface of the original R, and is a view when viewing the front surface of the original R from above (+Z direction side). As shown in FIG. 2, the front surface of the original R can include a pattern region R₁ including a pattern to be transferred onto the substrate, and a peripheral region R₂ around the pattern region R₁ in the X direction. The pattern region R₁ of the original R may be understood as a region (illumination region or exposure region) illuminated by the illumination optical system 1 in the forming apparatus 100a. The peripheral region R₂ of the original R may be understood as a region other than the pattern region R₁.

An example of the configuration of the hand 14a that holds the original R in the second conveyance mechanism 14 will be described next with reference to FIGS. 3A and 3B. FIG. 3A is a schematic view showing an example of the configuration of the hand 14a of the second conveyance mechanism 14, and is a view when viewing the hand 14a from below (-Z direction side). The hand 14a of the second conveyance mechanism 14 includes a plurality of suction pads 141 (holders) that hold the original R by vacuum suction or the like while contacting parts of the original R. By aligning the original R by the alignment stage 13, a reference position Rr (for example, the position of the center of gravity, see FIG. 2) of the original R and a reference position 140 (for example, the position of the center of gravity) of the hand 14a substantially coincide with each other. The plurality of suction pads 141 are arranged to hold the original R while contacting parts of the peripheral region R₂ of the front surface of the original R in the state in which alignment is performed in this way.

FIG. 3B is an enlarged view of one suction pad 141. The suction pad 141 includes an intake hole 142 for performing vacuum suction, and an outer edge portion 143 for defining a space where vacuum suction is performed via the intake hole 142. The outer edge portion 143 is a portion contacting the front surface of the original R. As shown in FIG. 2, contact regions R_{c}, contacting the suction pads 141 (outer edge portions 143), of the front surface of the original R are included in the peripheral region R₂.

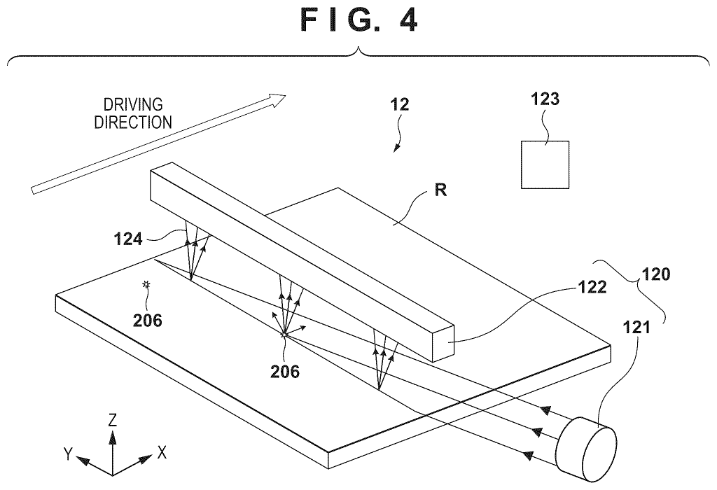

An example of the configuration of the foreign particle inspection device 12 will be described next with reference to FIG. 4. FIG. 4 is a schematic view showing an example of the configuration of the foreign particle inspection device 12. The foreign particle inspection device 12 includes a foreign particle detector 120 formed by a laser light source 121 and a line sensor 122. The foreign particle inspection device 12 includes a processor 123 that controls the foreign particle detector 120 and processes a signal output from the foreign particle detector 120 (line sensor 122).

For example, a plurality of foreign particle detectors 120 may be provided in the foreign particle inspection device 12 to inspect foreign particles on the front surface and back surface of the original R. FIG. 4 shows the foreign particle detector 120 for inspecting foreign particles on the front surface of the original R, and shows no foreign particle detector 120 for inspecting foreign particles on the back surface of the original R. The line sensor 122 extends in the Y direction, and the length of the line sensor 122 in the Y direction can be equal to or longer than the length of the original R in the Y direction. The foreign particle inspection device 12 includes a driving mechanism (not shown) that relatively drives the original R and the foreign particle detector 120 in a direction perpendicular to the extending direction (Y direction) of the line sensor 122. The relative driving range of the original R and the foreign particle detector 120 by the driving mechanism can be equal to or longer than the length of the original R in the X direction.

In the foreign particle inspection device 12, the laser light source 121 causes laser light to linearly, obliquely enter the front surface of the original R, and the line sensor 122 receives reflected light 124 from the front surface of the original R. The line sensor 122 is formed by arraying a plurality of sets of photoelectric conversion elements and optical systems (for example, lenses) in a line in the Y direction. Then, the foreign particle inspection device 12 can inspect foreign particles on the entire front surface of the original R by relatively driving the original R and the foreign particle detector 120 in a direction (X direction) perpendicular to the line of the laser light emitted to the front surface of the original R.

The processor 123 sequentially receives signals output from the line sensor 122, and generates a foreign particle adhesion distribution on the front surface of the original R based on the signals. If, as shown in FIG. 4, foreign particles 206 adhere to the front surface of the original R, the laser light from the laser light source 121 is scattered by the foreign particle 206 and received as scattered light by the line sensor 122. Therefore, the size of the reflected light (scattered light), the relative position in the X direction between the original R and the foreign particle detector 120 when the line sensor 122 receives the scattered light, and the position, in the Y direction, of the sensor that receives the scattered light in the line sensor 122 are obtained from the output signal of the line sensor 122. The processor 123 can calculate the size and position of each foreign particle on the front surface of the original R based on these pieces of information, and generate a foreign particle adhesion distribution representing the size and position as a map on the X-Y plane.

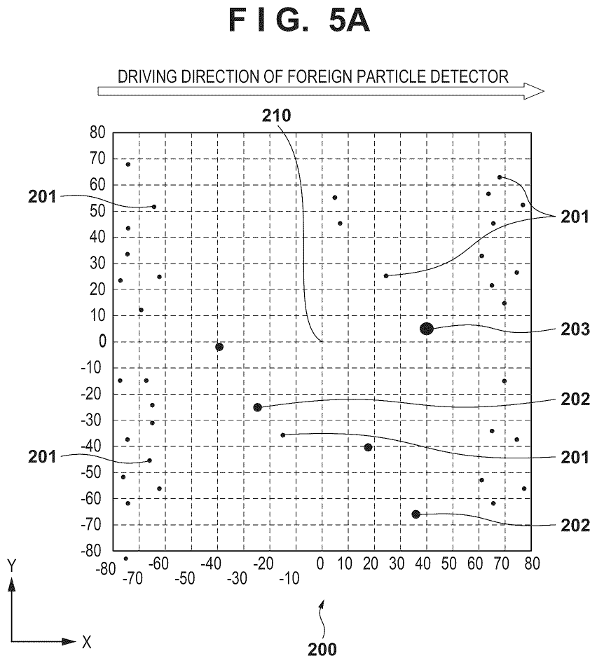

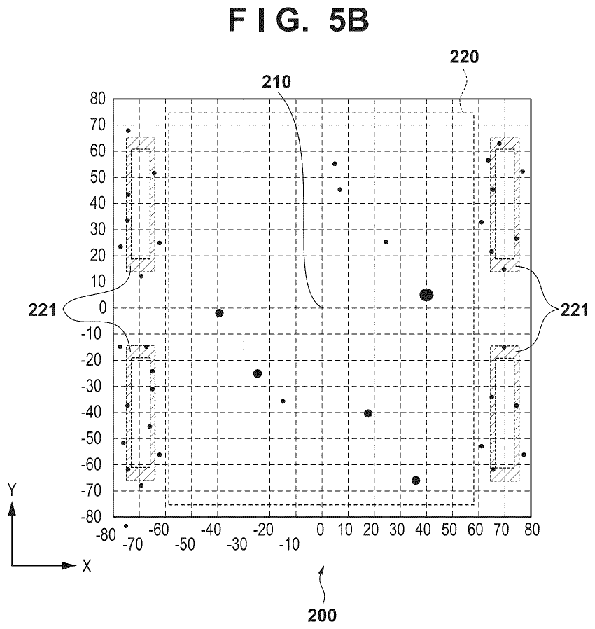

FIG. 5A is a view showing an example of a foreign particle adhesion distribution 200 acquired (measured) by the foreign particle inspection device 12. As described above, the foreign particle adhesion distribution 200 is obtained by generating, as a map, the sizes and positions of the foreign particles adhering to the front surface of the original R by receiving reflected light (scattered light) by the line sensor 122 while relatively driving the original R and the foreign particle detector 120 in the X direction. A coordinate “0” in the Y direction in the foreign particle adhesion distribution 200 represents the reference position (for example, the center position or the position of the center of gravity) of the line sensor 122, and a coordinate “0” in the X direction represents the reference position (for example, the center position or the position of the center of gravity) of a driving stroke of the foreign particle detector 120 with respect to the original R. That is, the coordinates (0, 0) in the foreign particle adhesion distribution 200 represent a position 210 corresponding to the reference position Rr of the original R.

In the foreign particle adhesion distribution 200, in accordance with the magnitude of the scattered light signal, the size of the foreign particle adhering to the front surface of the original R is classified into a small, medium, or large diameter and indicated. The foreign particle adhesion distribution 200 shown in FIG. 5A indicates that small-diameter foreign particles 201, medium-diameter foreign particles 202, and large-diameter foreign particles 203 adhere to the original R.

In a case where many foreign particles adhere to the contact region Rc of the front surface of the original R, which contacts the hand 14a (outer edge portion 143) of the second conveyance mechanism 14, even if the suction force of the hand 14a is sufficient, a frictional force between the hand 14a and the original R may be reduced. If the hand 14a is driven at a high speed in this state, the original R slips off the hand 14a, and the relative position between the hand 14a and the original R deviates. As a result, it is impossible to accurately convey the original R onto the original stage 2, and it may take extra time to position the original R by the forming apparatus 100a. In addition, when foreign particles are sandwiched between the hand 14a and the original R, the original R may be distorted. To cope with this, the original conveyance apparatus 100b according to this embodiment controls conveyance of the original R by the second conveyance mechanism 14 in accordance with the foreign particles (specific foreign particles), obtained from the inspection result (measurement result) of the foreign particle inspection device 12, in the contact region Rc of the front surface of the original R, which contacts the hand 14a (outer edge portion 143). The original conveyance apparatus 100b according to this embodiment controls conveyance of the original R by the second conveyance mechanism 14 further in accordance with the foreign particles in the pattern region R₁ of the front surface of the original R, which includes the pattern to be transferred onto the substrate.

FIG. 5B is a view showing a region 221 (to be sometimes referred to as the contact equivalent region 221 hereinafter) corresponding to the contact region Rc of the original R, which is superimposed on the foreign particle adhesion distribution 200 acquired by the foreign particle inspection device 12. Assuming that the reference position Rr of the original R and the reference position 140 of the hand 14a of the second conveyance mechanism 14 coincide with each other, the contact equivalent region 221 can be shown on the foreign particle adhesion distribution 200. The controller CNT can obtain a foreign particle adhesion status representing the size and position of each foreign substance adhering to the contact region Rc of the front surface of the original R by collating (comparing) the foreign particle adhesion distribution 200 and the contact equivalent region 221 with each other. Note that FIG. 5B also shows a region 220 (to be sometimes referred to as the pattern equivalent region 220 hereinafter) corresponding to the pattern region R₁ of the original R, which is superimposed on the foreign particle adhesion distribution 200.

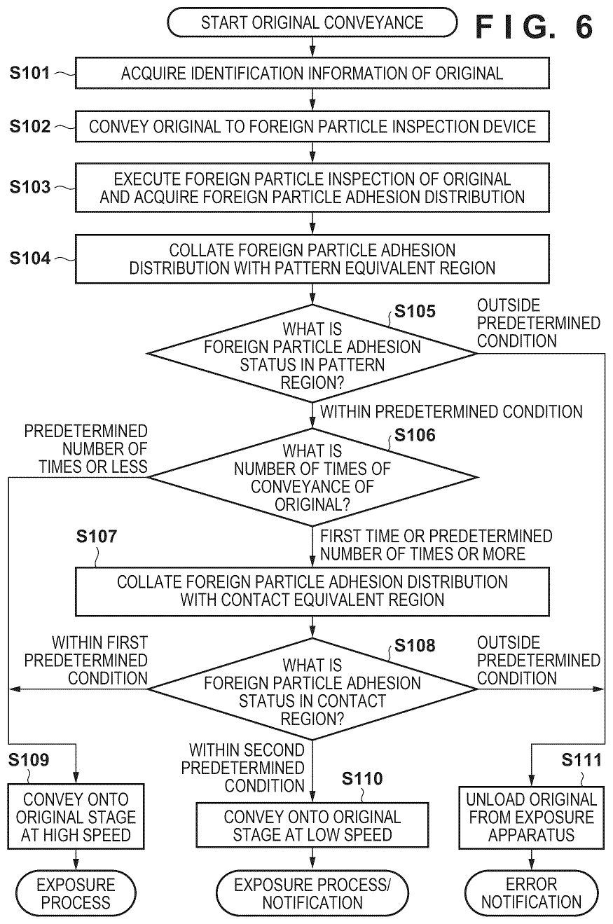

The method of conveying the original R in the original conveyance apparatus 100b according to this embodiment will be described next. FIG. 6 is a flowchart illustrating a method of conveying the original R from the reticle stocker 11 to the original stage 2 of the forming apparatus 100a in the original conveyance apparatus 100b according to this embodiment. The flowchart shown in FIG. 6 can be executed by the controller CNT.

In step S101, the controller CNT acquires the identification information (ID) of the original R to be conveyed to the original stage 2 of the forming apparatus 100a. For example, the controller CNT can acquire the identification information of the original R via the user interface UI. Next, in step S102, the controller CNT controls the first conveyance mechanism 9 to unload the original R corresponding to the identification information acquired in step S101 from the reticle stocker 11 and to convey the original R to the foreign particle inspection device 12.

In step S103, the controller CNT causes the foreign particle inspection device 12 to execute foreign particle inspection (that is, measurement of the foreign particle adhesion distribution 200) on the front surface of the original R. The foreign particle inspection by the foreign particle inspection device 12 is as described above. This allows the controller CNT to acquire the foreign particle adhesion distribution 200 from the foreign particle inspection device 12. After the end of the foreign particle inspection by the foreign particle inspection device 12, the controller CNT can cause the first conveyance mechanism 9 to convey the original R from the foreign particle inspection device 12 onto the alignment stage 13.

In step S104, the controller CNT collates the foreign particle adhesion distribution 200 acquired in step S103 with the pattern equivalent region 220. Next, in step S105, the controller CNT obtains a foreign particle adhesion status in the pattern region R₁ of the original R based on the collation result in step S104, and determines whether the foreign particle adhesion status in the pattern region R₁ satisfies a predetermined condition. The predetermined condition is, for example, a condition under which the specification of an exposure process can be satisfied with respect to the foreign particle adhesion status in the pattern region R₁ of the original R, and which can be preset by an experiment, a simulation, or the like.

For example, the controller CNT obtains, as the foreign particle adhesion status, the area occupancy ratio of the foreign particles in the pattern region R₁. In a case where the area occupancy ratio is lower than a predetermined value, the controller CNT can determine that the foreign particle adhesion status in the pattern region Ri satisfies the predetermined condition. The area occupancy ratio of the foreign particles in the pattern region R₁ can be calculated based on the sizes and amount of the foreign particles adhering to the pattern region R₁. Alternatively, the controller CNT obtains, as the foreign particle adhesion status, the amount of the foreign particles in the pattern region R₁. In a case where the amount of the foreign particles is smaller than a predetermined value, the controller CNT can determine that the foreign particle adhesion status in the pattern region R₁ satisfies the predetermined condition. Alternatively, the controller CNT may obtain, as the foreign particle adhesion status, the sizes of the foreign particles in the pattern region R₁. In this case, if a foreign particle of a size larger than a predetermined size (for example, the medium-diameter foreign particle 202 and the large-diameter foreign particle 203) does not exist in the pattern region R₁, the controller CNT can determine that the foreign particle adhesion status in the pattern region R₁ satisfies the predetermined condition.

If the foreign particle adhesion status in the pattern region R₁ satisfies the predetermined condition, the process advances to step S106. On the other hand, if the foreign particle adhesion status in the pattern region R₁ does not satisfy the predetermined condition, the process advances to step S111.

In step S106, the controller CNT determines whether the number of times of conveyance of the original R by the second conveyance mechanism 14 until now is one or a predetermined number or more. If the number of times of conveyance of the original R by the second conveyance mechanism 14 is one, when the original R is loaded to the exposure apparatus 100, many foreign particles may already adhere to the peripheral region R₂ (contact region Rc) on the front surface of the original R. Alternatively, if the number of times of conveyance of the original R by the second conveyance mechanism 14 is the predetermined number or more, many foreign particles may be accumulated in the peripheral region R₂ (contact region Rc) on the front surface of the original R along with conveyance until now. The predetermined number is, for example, an upper limit number with which a deviation of the relative position between the hand 14a and the original R, which may occur during conveyance of the original R by the second conveyance mechanism 14, can fall within an allowable range, and can be preset by an experiment, a simulation, or the like. If the number of times of conveyance of the original R by the second conveyance mechanism 14 is one or a predetermined number or more, the process advances to step S107. If the number of times of conveyance is smaller than the predetermined number (except for one), the process advances to step S109.

In step S106 according to this embodiment, the number of times of conveyance of the original R by the second conveyance mechanism 14 is determined, but the disclosure is not limited to this. For example, a period during which the reticle stocker 11 (storage) stores the original R before performing foreign particle inspection by the foreign particle inspection device 12 (that is, before measurement of the foreign particle adhesion distribution) may be determined. The original R stored in the reticle stocker 11 may accumulate more foreign particles on the front surface of the original R as the storage period is longer. In this case, in step S106, the controller CNT determines whether the storage period of the original R in the reticle stocker 11 (storage) is equal to or longer than a predetermined period. If the storage period is equal to or longer than the predetermined period, the process advances to step S107. If the storage period is shorter than the predetermined period, the process advances to step S109.

In step S107, the controller CNT collates the foreign particle adhesion distribution 200 acquired in step S103 with the contact equivalent region 221. Next, in step S108, the controller CNT obtains a foreign particle adhesion status in the contact region Rc of the original R based on the collation result in step S107, and determines whether the foreign particle adhesion status in the contact region Rc satisfies a first predetermined condition or a second predetermined condition. The first predetermined condition and the second predetermined condition are conditions for the foreign particle adhesion status in the contact region Rc, and can be preset by an experiment, a simulation, or the like. The first predetermined condition is, for example, a condition under which even if the second conveyance mechanism 14 conveys the original R at a first conveyance speed (high speed), a deviation of the relative position between the hand 14a and the original R, which may occur during conveyance, can fall within an allowable range. The second predetermined condition is, for example, a condition under which if the second conveyance mechanism 14 conveys the original R at a second conveyance speed (low speed) lower than the first conveyance speed, a deviation of the relative position between the hand 14a and the original R, which may occur during conveyance, can fall within an allowable range.

For example, the controller CNT can obtain, as the foreign particle adhesion status, the area occupancy ratio of the foreign particles in the contact region Rc, and determine, in accordance with the area occupancy ratio, whether the foreign particle adhesion status in the contact region Rc satisfies the first predetermined condition or the second predetermined condition. The area occupancy ratio of the foreign particles in the contact region Rc can be calculated based on the sizes and amount of the foreign particles adhering to the contact region Rc. As an example, in a case where the area occupancy ratio of the foreign particles in the contact region Rc is lower than a first predetermined value (for example, less than 3%), it is determined that the first predetermined condition is satisfied. In a case where the area occupancy ratio is lower than a second predetermined value (for example, less than 10% or more), it is determined that the second predetermined condition is satisfied. In a case where the area occupancy ratio is equal to or higher than the second predetermined value (for example, 10%), it is determined that neither the first predetermined condition nor the second predetermined condition is satisfied.

Alternatively, the controller CNT can obtain, as the foreign particle adhesion status, the amount of the foreign particles in the contact region Rc, and determine, in accordance with the amount of the foreign particles, whether the foreign particle adhesion status in the contact region Rc satisfies the first predetermined condition or the second predetermined condition. Alternatively, the controller CNT may obtain, as the foreign particle adhesion status, the sizes of the foreign particles in the contact region Rc, and determine, in accordance with the sizes of the foreign particles, whether the foreign particle adhesion status in the contact region Rc satisfies the first predetermined condition or the second predetermined condition. As an example, if neither the medium-diameter foreign particle 202 nor the large-diameter foreign particle 203 exists in the contact region Rc, the controller CNT can determine that the first predetermined condition is satisfied. If, in the contact region Rc, the medium-diameter foreign particle 202 exists but the large-diameter foreign particle 203 does not exist, the controller CNT can determine that the second predetermined condition is satisfied.

If the foreign particle adhesion status in the contact region Rc satisfies the first predetermined condition, the process advances to step S109. In step S109, the controller CNT causes the second conveyance mechanism 14 to convey the original R onto the original stage 2 at the first conveyance speed (high speed). In this case, the forming apparatus 100a performs an exposure process using the original R as usual.

On the other hand, if the foreign particle adhesion status in the contact region Rc satisfies not the first predetermined condition but the second predetermined condition, the process advances to step S110. In step S110, the controller CNT causes the second conveyance mechanism 14 to convey the original R onto the original stage 2 at the second conveyance speed (low speed). In this case, the forming apparatus 100a performs an exposure process using the original R as usual. In addition, the controller CNT notifies, via the user interface UI, the user that the amount of the foreign particles adhering to the original R is increased. This notification may be performed, for example, after the end of the exposure process.

If the foreign particle adhesion status in the contact region Rc satisfies neither the first predetermined condition nor the second predetermined condition, the process advances to step S111. In step S111, the controller CNT causes the first conveyance mechanism 9 to convey the original R to the pod opener 7 or 8, thereby unloading the original R from the exposure apparatus 100. In this case, an exposure process using the original R is not performed. Then, the controller CNT notifies (error notification), via the user interface UI, the user that the original R cannot be conveyed onto the original stage 2 by the second conveyance mechanism 14 due to the amount of the foreign particles adhering to the original R. Note that the controller CNT may perform notification to prompt cleaning of the original R. Since, in step S111, the original R is conveyed to the pod opener 7 or 8, the conveyance destination of the original R conveyed to the original stage 2 in step S109 or S110 is made different. That is, the conveyance destination of the original R is changed in accordance with the foreign particle adhesion status in the contact region Rc.

As described above, the original conveyance apparatus 100b according to this embodiment obtains, from the foreign particle adhesion distribution, the foreign particle adhesion status in the contact region Rc on the front surface of the original R, and controls conveyance of the original R by the second conveyance mechanism 14 in accordance with the foreign particle adhesion status in the contact region Rc. This can appropriately control conveyance of the original R by the second conveyance mechanism 14. In this embodiment, the upper surface of the original R has been exemplified as the front surface of the original R that the hand 14a of the second conveyance mechanism 14 contacts, but the front surface of the original R may be the lower surface of the original R. In this case, conveyance of the original R by the second conveyance mechanism 14 can be controlled in accordance with the foreign particle adhesion status obtained by the foreign particle inspection device 12 with respect to the lower surface of the original R.

### Second Embodiment

The second embodiment of the disclosure will be described. The above first embodiment has explained the example of performing foreign particle inspection for the entire front surface of the original R by the foreign particle inspection device 12. This embodiment will describe an example of performing foreign particle inspection of a peripheral region R₂ without performing foreign particle inspection of a pattern region R₁ on the front surface of an original R. Note that this embodiment basically inherits the first embodiment and can follow the first embodiment except for matters referred to below.

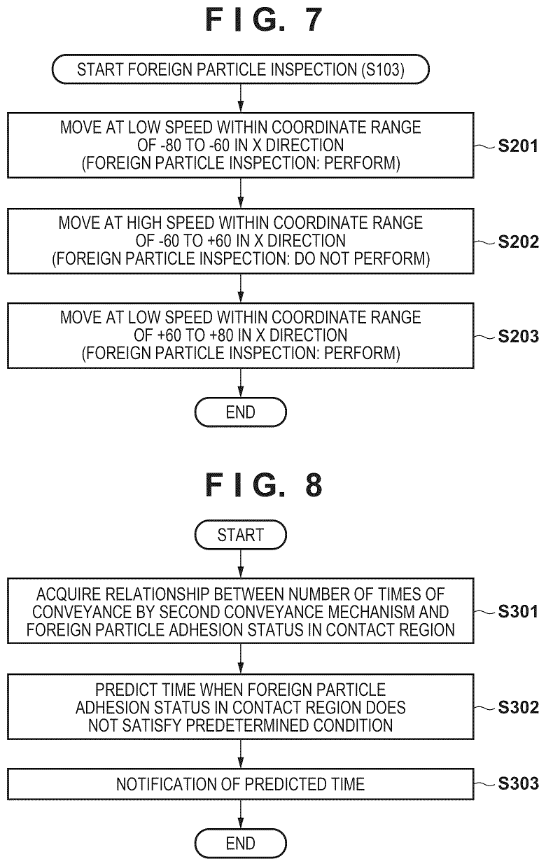

FIG. 7 is a flowchart illustrating foreign particle inspection (that is, measurement of a foreign particle adhesion distribution) performed in step S103 of FIG. 6 according to this embodiment. In this embodiment, foreign particle inspection can be performed for the peripheral region R₂ on the front surface of the original R. Foreign particle inspection of this embodiment will be described below in accordance with the coordinate system shown in FIGS. 5A and 5B. In this embodiment, in the flowchart shown in FIG. 6, steps S104 to S105 may be omitted. Steps S102 and S103 may be performed between steps S106 and S107.

In step S201, a controller CNT performs foreign particle inspection while relatively driving the original R and a foreign particle detector 120 in the X direction at a first driving speed (low speed) within a coordinate range of −80 to −60 in the X direction. This can obtain a foreign particle adhesion distribution within the coordinate range of −80 to −60 in the X direction. The coordinate range of −80 to −60 in the X direction is a range corresponding to the peripheral region R₂ including a contact region Rc on the front surface of the original R. The first driving speed can be set to a relative speed between the original R and the foreign particle detector 120, at which foreign particle inspection can be performed by the foreign particle detector 120.

In step S202, the controller CNT relatively drives the original R and the foreign particle detector 120 in the X direction at a second driving speed (high speed) higher than the first driving speed within a coordinate range of −60 to +60 in the X direction. In step S202, no foreign particle inspection is performed by the foreign particle detector 120. Therefore, the relative driving speed between the original R and the foreign particle detector 120 can be set to the second driving speed higher than the first driving speed, which can be advantageous in terms of throughput. The coordinate range of −60 to +60 in the X direction is a range corresponding to the pattern region R₁ on the front surface of the original R. The second driving speed is set to a speed higher than the maximum relative speed between the original R and the foreign particle detector 120, at which foreign particle inspection can be performed by the foreign particle detector 120.

In step S203, the controller CNT performs foreign particle inspection while relatively driving the original R and the foreign particle detector 120 in the X direction at a third driving speed (low speed) within a coordinate range of +60 to +80 in the X direction. This can obtain a foreign particle adhesion distribution within the coordinate range of +60 to +80 in the X direction. The coordinate range of +60 to +80 in the X direction is a range corresponding to the peripheral region R2 including the contact region Rc on the front surface of the original R. The third driving speed can be set to a relative speed between the original R and the foreign particle detector 120, at which foreign particle inspection can be performed by the foreign particle detector 120. The third driving speed is a speed lower than the second driving speed, and may be equal to the first driving speed.

As described above, in the second embodiment, within the range (the coordinate range of −80 to −60 in the X direction or the coordinate range of +60 to +80 in the X direction) corresponding to the peripheral region R₂, foreign particle inspection is performed while relatively driving the original R and the foreign particle detector 120 in the X direction at the first driving speed or the third driving speed (low speed). On the other hand, within the range (the coordinate range of −60 to +60 in the X direction) corresponding to the pattern region R₁, the original R and the foreign particle detector 120 are relatively driven in the X direction at the second driving speed (high speed) but no foreign particle inspection is performed. This can appropriately perform foreign particle inspection of the peripheral region R₂ on the front surface of the original R and can also be advantageous in terms of throughput.

### Third Embodiment

The third embodiment of the disclosure will be described. This embodiment will describe an example in which a time when a foreign particle adhesion status in a contact region Rc does not satisfy a predetermined condition under which a second conveyance mechanism 14 can convey an original R is predicted based on a result of performing foreign particle inspection (measurement of a foreign particle adhesion distribution) for the original R by a foreign particle inspection device 12 a plurality of times and notification is performed. The predetermined condition can include at least one of a first predetermined condition and a second predetermined condition. Both the first predetermined condition and the second predetermined condition will be exemplified as the predetermined condition below. Note that this embodiment basically inherits the first embodiment and can follow the first embodiment except for matters referred to below. In this embodiment, the second embodiment may be applied.

FIG. 8 is a flowchart illustrating a method of predicting a time when the foreign particle adhesion status in the contact region does not satisfy the predetermined condition (the first predetermined condition and the second predetermined condition) and performing notification. The flowchart shown in FIG. 8 can be executed by a controller CNT. In this example, in step S108 of FIG. 6, the controller CNT stores the foreign particle adhesion status obtained with respect to the contact region Rc of the original R in a storage unit in correspondence with the number of times of conveyance of the original R by the second conveyance mechanism 14. The flowchart shown in FIG. 8 can be executed, for example, every time the foreign particle adhesion status in the contact region Rc is obtained in step S108.

In step S301, the controller CNT acquires the relationship between the number of times of conveyance by the second conveyance mechanism 14 and the foreign particle adhesion status in the contact region Rc. As described above, as the foreign particle adhesion status, the area occupancy ratio of foreign particles in the contact region Rc may be used or the amount or sizes of the foreign particles in the contact region Rc may be used.

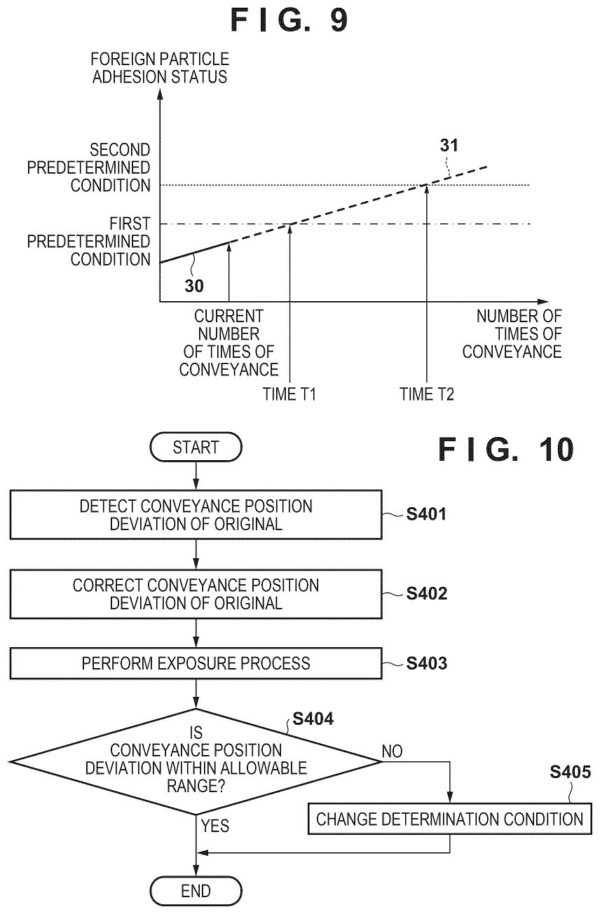

In step S302, the controller CNT predicts a time (the number of times of conveyance) when the foreign particle adhesion status in the contact region Rc does not satisfy the predetermined condition based on the relationship between the number of times of conveyance and the foreign particle adhesion status, which has been acquired in step S301. FIG. 9 is a graph showing an example of the relationship between the number of times of conveyance and the foreign particle adhesion status. For example, the controller CNT obtains an approximation function 31 (for example, an approximate straight line) with respect to an obtained relationship 30 between the number of times of conveyance and the foreign particle adhesion status. This allows the controller CNT to predict, based on the approximation function 31, a time T1 (the number of times of conveyance) when the first predetermined condition is reached and a time T2 (the number of times of conveyance) when the second predetermined condition is reached. Note that the time T2 may be understood as a time when the original R should be cleaned.

In step S303, the controller CNT notifies, via a user interface UI, the user of the times T1 and T2 predicted in step S302. For example, the controller CNT may notify the user of the times T1 and T2 by displaying them on the display of the user interface UI. This embodiment has explained the example of notifying the user of both the time T1 when the first predetermined condition is reached and the time T2 when the second predetermined condition is reached. However, the disclosure is not limited to this, and the controller CNT may notify the user of the time T2. Alternatively, the controller CNT may notify the user of the time T1.

As described above, in this embodiment, the time when the foreign particle adhesion status in the contact region Rc of the original R does not satisfy the predetermined condition is predicted based on the obtained relationship between the number of times of conveyance and the foreign particle adhesion status and notification is performed. This allows the user (operator) to perform an appropriate countermeasure such as cleaning of the original R before the foreign particle adhesion status in the contact region Rc does not satisfy the predetermined condition.

### Fourth Embodiment

The fourth embodiment of the disclosure will be described. This embodiment will describe an example in which a predetermined condition for determining whether to convey an original R by a second conveyance mechanism 14 is changed in accordance with a position deviation of the original R conveyed onto an original stage 2 (member) by the second conveyance mechanism 14. The predetermined condition can include at least one of a first predetermined condition and a second predetermined condition. Both the first predetermined condition and the second predetermined condition will be exemplified as the predetermined condition below. Note that this embodiment basically inherits the first embodiment and can follow the first embodiment except for matters referred to below. In this embodiment, the second embodiment may be applied or the third embodiment may be applied.

FIG. 10 is a flowchart illustrating a method of changing a predetermined condition in accordance with the position deviation of the original R conveyed onto the original stage 2 by the second conveyance mechanism 14. The flowchart shown in FIG. 10 can be executed by a controller CNT after the original R is conveyed onto the original stage 2 through step S109 or S110 in the flowchart of FIG. 6. As shown in FIG. 1, a detector 15 that detects the position of the original R on the original stage 2 can be provided in an exposure apparatus 100 (forming apparatus 100a) of this embodiment. The detector 15 may be understood as a detector that detects a deviation (to be sometimes referred to as a conveyance position deviation hereinafter) between a target position on the original stage 2 to which the original R is to be conveyed (arranged) and a position to which the original R is actually conveyed by the second conveyance mechanism 14. For example, the detector 15 can be configured to detect a conveyance position deviation by detecting an alignment mark provided on the original R.

In a case where a conveyance position deviation occurs in the original R conveyed onto the original stage 2 by the second conveyance mechanism 14, the original R being conveyed by the second conveyance mechanism 14 may slip off a hand 14a, and thus the relative position between the hand 14a and the original R may deviate. In this case, the predetermined condition (first predetermined condition and second predetermined condition) for determining whether to convey the original R by the second conveyance mechanism 14 may be inappropriate. To cope with this, in this embodiment, the conveyance position deviation of the original R on the original stage 2 is detected, and the predetermined condition is changed based on the conveyance position deviation.

In step S401, the controller CNT causes the detector 15 to detect the conveyance position deviation of the original R. In step S402, the controller CNT corrects the conveyance position deviation of the original R. In step S403, the controller CNT performs an exposure process.

In step S404, the controller CNT determines whether the conveyance position deviation of the original R detected in step S401 falls within an allowable range. If the conveyance position deviation of the original R falls within the allowable range, the process ends. If the conveyance position deviation of the original R falls outside the allowable range, the process advances to step S405. In step S405, the controller CNT changes the predetermined condition (first predetermined condition and second predetermined condition) for determining whether to convey the original R by the second conveyance mechanism 14. For example, if the conveyance position deviation of the original R falls outside the allowable range, the controller CNT determines that the relative position between the hand 14a and the original R deviates during conveyance of the original R by the second conveyance mechanism 14, and changes the predetermined condition to be stricter. As an example, in a case where the area occupancy ratio of foreign particles in a contact region Rc is used as a foreign particle adhesion status, the controller CNT can change, as the first predetermined condition, a first predetermined value associated with the area occupancy ratio of the foreign particles in the contact region Rc from a value lower than 3% to a value lower than 2%. Furthermore, the controller CNT changes, as the second predetermined condition, a second predetermined value associated with the area occupancy ratio of the foreign particles in the contact region Rc from a value lower than 10% to a value lower than 8%.

As described above, in this embodiment, the predetermined condition (first predetermined condition and second predetermined condition) for determining whether to convey the original R by the second conveyance mechanism 14 is changed in accordance with the conveyance position deviation of the original R conveyed onto the original stage 2 by the second conveyance mechanism 14. This can appropriately control conveyance of the original R by the second conveyance mechanism 14. In this embodiment, steps S404 and S405 are performed after steps S402 and S403. However, the disclosure is not limited to this, and steps S404 and S405 may be performed before steps S402 and S403 or simultaneously with steps S402 and S403.

### Embodiment of Article Manufacturing Method

An article manufacturing method according to the embodiment of the disclosure is suitable for manufacturing an article, for example, a microdevice such as a semiconductor device or a device having a microstructure. The article manufacturing method according to this embodiment includes a forming step of forming a pattern on a substrate using the above-described lithography apparatus (exposure apparatus), a processing step of processing the substrate on which the pattern has been formed in the forming step, and a manufacturing step of manufacturing an article from the substrate processed in the processing step. The manufacturing method further includes other known steps (oxidation, film formation, deposition, doping, planarization, etching, resist removal, dicing, bonding, packaging, and the like). The article manufacturing method of this embodiment is more advantageous than the conventional methods in at least one of the performance, quality, productivity, and production cost of the article.

### Other Embodiments

Embodiment(s) of the disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD) TM), a flash memory device, a memory card, and the like.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-106281 filed on Jul. 1, 2024, which is hereby incorporated by reference herein in its entirety.

What is claimed is:

1. An apparatus comprising:
a measurement device configured to measure foreign particles on a surface of an object;
a conveyer including a holder configured to hold the object while contacting a part of the surface of the object, and configured to convey the object for which the foreign particles have been measured, while holding the object by the holder; and
a controller configured to control conveying the object by the conveyer, in accordance with specific foreign particles in a contact region to which the holder contacts among the surface of the object, wherein the specific foreign particles are obtained from a measurement result of the measurement device.

2. The apparatus according to claim 1, wherein
the surface of the object includes a pattern region including a pattern to be transferred onto a substrate, and a peripheral region existing around the pattern region and including the contact region, and
the controller further controls conveying the object in accordance with foreign particles in the pattern region obtained from the measurement result.

3. The apparatus according to claim 1, wherein the controller controls conveying the object further based on number of times the object is conveyed.

4. The apparatus according to claim 1, further comprising a storage configured to store the object before measurement by the measurement device,
wherein the controller controls conveying the object further based on a period during which the storage stores the object.

5. The apparatus according to claim 1, wherein the controller changes a conveyance speed of the object in accordance with the specific foreign particles in the contact region.

6. The apparatus according to claim 1, wherein the controller changes a conveyance destination of the object in accordance with the specific foreign particles in the contact region.

7. The apparatus according to claim 1, wherein the controller obtains, as a foreign particle adhesion status in the contact region, an area occupancy ratio of the specific foreign particles in the contact region from the measurement result.

8. The apparatus according to claim 1, wherein the controller obtains, as a foreign particle adhesion status in the contact region, at least one of an amount and a size of the specific foreign particles in the contact region from the measurement result.

9. The apparatus according to claim 1, wherein
the surface of the object includes a pattern region including a pattern to be transferred onto a substrate, and a peripheral region existing around the pattern region and including the contact region, and
the measurement device measures the foreign particles within a range including the pattern region and the peripheral region.

10. The apparatus according to claim 1, wherein
the surface of the object includes a pattern region including a pattern to be transferred onto a substrate, and a peripheral region existing around the pattern region and including the contact region, and
the measurement device measures the foreign particles in the peripheral region.

11. The apparatus according to claim 1, wherein based on a result of performing measurement for the object by the measurement device a plurality of times, the controller predicts a time at which the specific foreign particles in the contact region does not satisfy a predetermined condition under which the conveyer can convey the object, and performs notification.

12. The apparatus according to claim 1, wherein the controller causes the conveyer to convey the object onto a member in a case where the specific foreign particles in the contact region obtained from the measurement result satisfies a predetermined condition, and changes the predetermined condition in accordance with a position deviation of the object conveyed onto the member by the conveyer.

13. The apparatus according to claim 12, wherein the object is an original including a pattern to be transferred to a substrate, and the member is an original stage configured to be movable while holding the original.

14. A lithography apparatus comprising:
the apparatus defined in claim 1,
wherein the apparatus conveys a substrate or an original including a pattern to be transferred to a substrate.

15. The lithography apparatus according to claim 14, wherein, in the apparatus,
the surface of the object includes a pattern region including a pattern to be transferred onto a substrate, and a peripheral region existing around the pattern region and including the contact region, and
the controller further controls conveying the object in accordance with foreign particles in the pattern region obtained from the measurement result.

16. The lithography apparatus according to claim 14, wherein, in the apparatus,
the controller controls conveying the object further based on number of times the object is conveyed.

17. The lithography apparatus according to claim 14, the apparatus further comprising a storage configured to store the object before measurement by the measurement device,
wherein the controller controls conveying the object further based on a period during which the storage stores the object.

18. The lithography apparatus according to claim 14, wherein, in the apparatus, the controller changes a conveyance speed of the object in accordance with the specific foreign particles in the contact region.

19. The lithography apparatus according to claim 14, wherein, in the apparatus, the controller changes a conveyance destination of the object in accordance with the specific foreign particles in the contact region.

20. An article manufacturing method comprising:
forming a pattern on a substrate using the lithography apparatus defined in claim 14;
processing the substrate on which the pattern has been formed; and
manufacturing an article from the processed substrate.
